(19) United States
(12) Patent Application Publication
(10) Pub. No.: US 2014/0063794 A1
(43) Pub. Date: Mar. 6, 2014

(54) CURVED PRINTED CIRCUIT BOARDS, LIGHT MODULES, AND METHODS FOR CURVING A PRINTED CIRCUIT BOARD

(71) Applicant: Esmail Khalid Parekh, Daimond Bar, CA (US)

(72) Inventor: Esmail Khalid Parekh, Daimond Bar, CA (US)

(73) Assignee: Foshan Innovative Lighting Co., Ltd., Foshan (CN)

(21) Appl. No.: 13/604,540

(22) Filed: Sep. 5, 2012

(51) Int. Cl. F21L 4/02; H05K 1/03; H05K 3/00; F21V 29/00

(52) U.S. Cl. 362/185; 362/184; 174/255; 29/829

(57) ABSTRACT

Curved printed circuit boards, light modules, and methods for curving a printed circuit board are disclosed. An example light module includes a curved printed circuit board having electrical connections and a plurality of light sources attached to the curved printed circuit board and electrically coupled to the electrical connections. A power supply is electrically coupled to the plurality of light sources through the electrical connections of the curved printed circuit board and is configured to provide power to the plurality of light sources. An example method for curving a printed circuit board includes forming a plurality of cuts on a substantially flat printed circuit board substrate and bending the printed circuit board substrate to form a curved printed circuit board.

### TECHNICAL FIELD

Embodiments of the present invention relate generally to light modules, and more specifically in one or more illustrated embodiment, to light modules having a curved printed circuit board on which a light source may be attached which may provide for a more even distribution for light.

### BACKGROUND OF THE INVENTION

Light-emitting diodes (LEDs) are light sources that are frequently used as indicator lamps in many devices and are increasingly used for other lighting. LEDs may present many advantages over incandescent light sources including lower energy consumption, longer lifetime, improved robustness, smaller size, faster switching, and greater durability and reliability. These and other advantages of LEDs may make them good candidates for many household residential and commercial uses.

A shortcoming of LEDs, especially when used for room lighting, is their directionality. That is, the light provided is generally emitted in the direction the LEDs are pointing. Thus, attaching LEDs to conventional flat printed circuit boards (PCBs) typically results in poor light dispersion and light distribution. Some have sought to solve this problem by attaching LEDs to multiple flat PCBs that are positioned at angled orientations with respect to each other such that a three dimensional form is attempted. This is an awkward and imperfect solution because of the complexity of connecting the multiple PCB circuits, and the complexity of the mounting structure, for example. Other approaches to dispersing light provided by LED light sources include using reflectors or lenses, neither of which may provide satisfactory results or may add complexity to the manufacturing process and increase manufacturing costs.

Therefore, there is a need for alternative configurations and method for dispersing light from light sources, for example, LED light sources.

### BRIEF DESCRIPTION OF THE DRAWINGS

FIG. 1 is a side view of a light module according to an embodiment of the invention.

FIG. 2 is an isometric exploded view of the light module depicted in FIG. 1.

FIG. 3 is a side view of a light module according to an embodiment of the invention.

FIG. 4 is an isometric exploded view of the light module depicted in FIG. 2.

FIGS. 5A-5C are side, plan, and isometric views of a printed circuit board according to an embodiment of the invention.

FIG. 6 is a flow diagram of a method for forming a curved printed circuit board according to an embodiment of the invention.

### DETAILED DESCRIPTION

Embodiments of the invention include printed circuit boards (PCBs) on which light sources may be attached and further includes methods for forming PCBs according to embodiments of the invention. Certain details are set forth below to provide a sufficient understanding of embodiments of the invention. However, it will be clear to one skilled in the art that embodiments of the invention may be practiced without these particular details. Moreover, the particular embodiments of the present invention described herein are provided by way of example and should not be used to limit the scope of the invention to these particular embodiments.

In an embodiment of the present invention, a light module having LED light sources is disclosed. The light module may consist of a curved PCB on which a plurality of LEDs are attached. The curvature of the PCB may improve distribution of light provided by the LEDs in comparison to conventional LED PCB mounting configurations. The light modules according to embodiments of the invention may be used for the replacement of incandescent and compact fluorescent lamps, in various lighting fixtures including but not limited to ceiling fixtures, wall fixtures, sconces and outdoor lanterns. Additionally, using a curved PCB according to an embodiment of the invention for attaching light sources may provide improved light distribution, while utilizing various conventional lampholder configurations. As such, the curved PCB may provide for easy retrofitting of existing ceiling light fixtures. Embodiments of the invention may also provide an alternative to conventional LED PCB mounting methods and allow for easy replacement in many conventional home ceiling light fixtures.

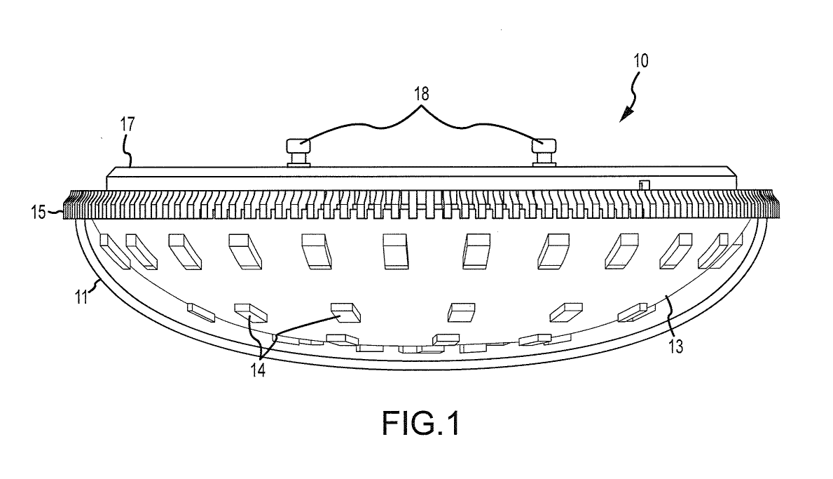

FIG. 1 illustrates a light module 10 according to an embodiment of the invention.

The light module 10 includes a covering 11, a curved PCB 13, a heat sink 15, a base plate 17, and a power supply 19. The covering 11 may be a lens, and may be formed from a clear or translucent material. The light module further includes a plurality of light sources 14 attached to the curved PCB 13. The covering 11 is configured to be coupled to the heat sink 15 such that when coupled an enclosed volume 12 is defined. The curved PCB 13 and the power source 19 may both be positioned within the enclosed volume 12. The PCB 13 may include a metallic substrate, for example, aluminum. Other types of metals may be used as well. The curved PCB 13 is formed having electrical connections configured to connect the light sources 14 to the power supply 19. The power supply 19 may be an LED driver and may be coupled to the base plate 17. The power supply may also be electrically coupled to an exterior circuit (not shown) via pins 18. The pins 18 may be configured to serve as electrical contacts to a conventional lampholder for supplying power to the plurality of light sources 14.

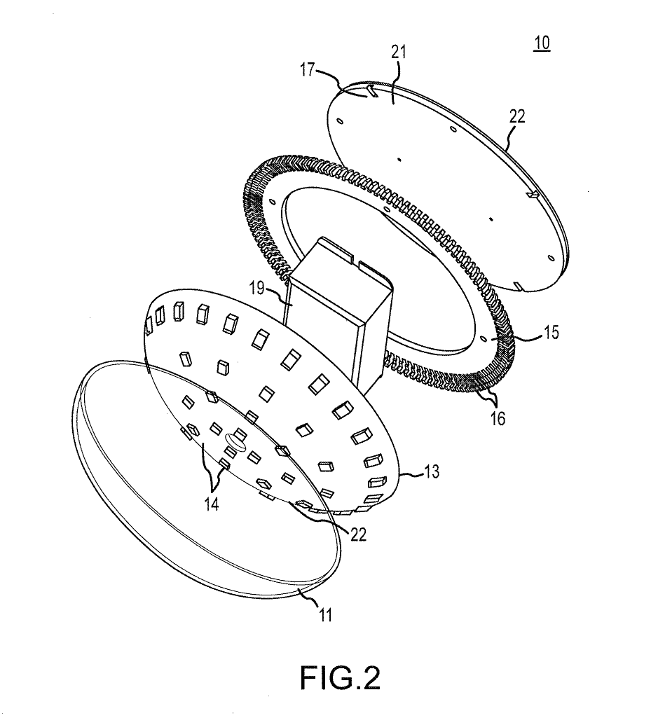

FIG. 2 is an exploded view of the light module 10 depicted in FIG. 1. The covering 11, curved PCB 13, heat sink 15, base plate 17, and power supply 19 are illustrated in the exploded view of the light module 10. As illustrated in FIG. 2, the covering 11 may be curved in a complementary shape to the curved PCB 13. The curvature of the PCB 13 may be spherical in shape (e.g., forming a dome shape), it may be cylindrical, or may be of any other desirable shape. The covering 11 may be a lens, or any other curved covering of clear or translucent material, for example, glass or plastic. As would be obvious to one of ordinary skill, the covering 11 may be formed from other non-opaque materials, which permit light to pass through the covering. The PCB 13 may be segmented such as to facilitate the forming of the PCB with a curved surface. The PCB 13 may be segmented by forming a plurality of cuts, slits, or notches, or any combination thereof, or by removing material as needed. The curved PCB 13 contains electrical connections such that one or more light source 14 or other circuit components may be attached to the PCB and electrically connected. The light source 14 may be a LED, and may be a surface mount LED. The curved PCB 13 includes a metal layer. For example, the curved PCB 13 may be a single layer PCB with aluminum base layer, and copper circuit layer, as an example. Other PCB configurations may be used as well. The heat sink 15 is positioned to be in thermal contact with the curved PCB 13. The heat sink 15 may have a plurality of fins 16 through which air may flow and facilitate heat dissipation. The fins 16 may be appropriately shaped to receive and retain the curved PCB 13. For example, the curved PCB 13 may snap into place when coupled to the heat sink 15. Other attachment configurations and methods may be used as would be apparent to one of ordinary skills.

The base plate 17 may be formed from a rigid material. For example, the base plate 17 may be plastic. The base plate 17 has a first surface 21 to which the heat sink 15 may be attached. The base plate 17 also has a second surface 22. In an embodiment of the invention, the power supply 19 may be attached to the first surface 21 of the base plate 17 and may be positioned such that it fits inside a volume defined by the curved PCB 13. The power supply 19 may be attached to the second surface 22 of the base plate 17. The power supply 19 is electrically connected through the electrical connections of the curved PCB 13 to provide power to illuminate the light sources 14. The power supply 19 may be electrically connected to an external power supply (not shown) through pins 18 (FIG. 1) when mounted to a light fixture, for example.

When assembled, as illustrated in FIG. 1, for example, all of the components of the light module 10 fit together to form a self-contained light module. The light module 10 may be easily mounted or dismounted from a conventional flush-mount ceiling light fixture. When mounted, the base plate 17 of light module 10 would be positioned close to the ceiling or other mounting surface.

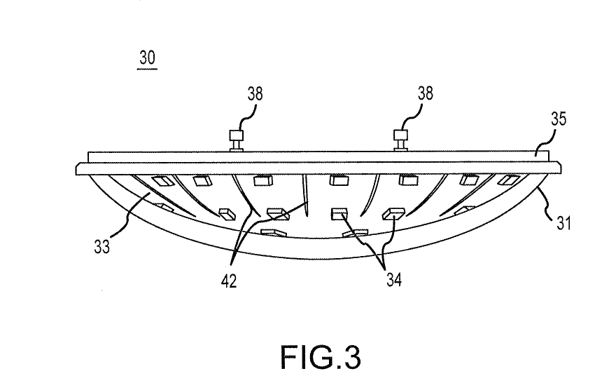

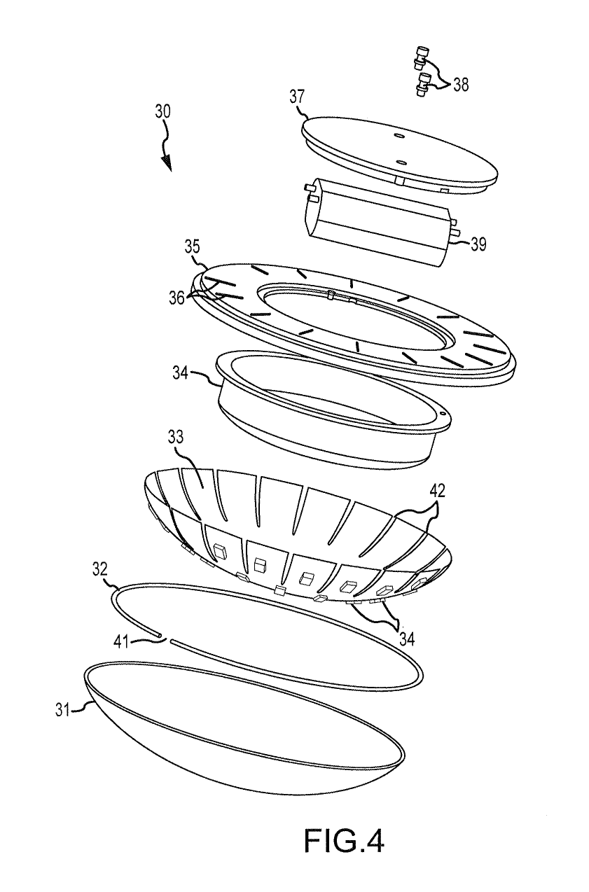

FIGS. 3 and 4 illustrate a light module 30 according to an embodiment of the invention. FIG. 3 is a side view of the assembled light module 30 and FIG. 4 is an exploded isometric view of the light module 30. The light module 30 includes a covering 31, a ring 32, a curved PCB 33, a first heat sink 34, a second heat sink 35, a mounting plate 37, and a power source 39. The ring 32 may be made of a metallic material. For example, the ring 32 may be steel, but as would be obvious to one of ordinary skill, other metals may be used as well. The ring 32 may be continuous or may have a gap. The gap may allow for expansion and contraction of the metal material due to thermal loads. As an example, the ring 32 may be tensioned such that it snaps into place when assembled with the curved PCB 33 into the second heat sink 35.

The curved PCB 33 includes electrical connections to which one or more light source 34 or other circuit components may be attached to the PCB 33 and electrically connected. The light sources 34 may be LED light sources. The curved PCB 33 may include cuts 42. The cuts 42 may facilitate formation of the curved PCB 33. The cuts 42 are apparent in one embodiment of the invention as depicted in FIGS. 3 and 4. However, in other embodiments, the cuts 42 are less apparent or not apparent on the curved PCB 33. The dimensions of the cuts 42 made during formation of the curved PCB 33 may affect the appearance of the cuts 42. The radius of the curvature of the curved PCB 33 may affect the appearance of the cuts 42 as well. The curved PCB 33 may include a metal base layer and a conductive layer. For example, the curved PCB 33 may include an aluminum base layer and further include a copper conductive layer from which the electrical connections are formed. The power supply 39 may be attached to the base plate 37. Pins 38 are attached to the base plate 37 and may be used for mounting the light module 30 to a light fixture. In some embodiments, the pins 38 may be electrical connectors. In some embodiments, additional fasteners may be provided for mounting the light module to a light fixture. The power supply 39 is electrically connected through the electrical connections of the curved PCB 33 to provide power to illuminate the light sources 34. The power supply 39 may be electrically connected to an external power supply (not shown) through pins 38 when mounted to a light fixture, for example.

The first heat sink 34 may be formed from a metallic material to allow for heat transfer and heat dissipation from the curved PCB 33. The first heat sink 34 is positioned inside a region formed by the curved PCB 33 and is in thermal contact with the PCB 33. Contact between the PCB 33 and the first heat sink 34 allows for heat transfer between the PCB 33 and the first heat sink 34. The heat sink 34 may be coupled to the curved PCB 33 using a thermally conductive adhesive or thermal grease. The adhesive may be a silicon, an epoxy, or other suitable elastomeric material. The first (inner) heat sink may have fins (not shown) for increased heat dissipation. The second heat sink 35 may be coupled to the inner heat sink 34. The second heat sink 35 may be formed from a metallic material. For example, the second heat sink 35 may be steel, but as would be obvious to one of ordinary skill, may be manufactured from aluminum or other metallic materials or combination thereof. The second heat sink 35 may have a plurality of slits 35 therethrough, providing for increased surface area and improved air flow for dissipating heat. In some embodiments, the second heat sink 35 may have fins (not shown) in addition to or instead of the slits 35.

As would be appreciated by those skilled in the art, multiple heat sinks may be used to achieve sufficient thermal management for some LED applications. The outer heat sink may have a round circumference to accommodate a spherically shaped PCB. However, as it would be appreciated by those skilled in the art, other shapes of curved PCBs may be used, and accordingly other shapes of heat sinks may be appropriately used to accommodate the three-dimensionally shaped PCBs. Also, as will be apparent to one of ordinary skill, the light module may be formed in any desirable size. Preferably the light module is sized such that it fits within any conventional ceiling light fixture or other light fixtures. Example of such light fixtures may vary in diameter as suitable for the light fixture or application.

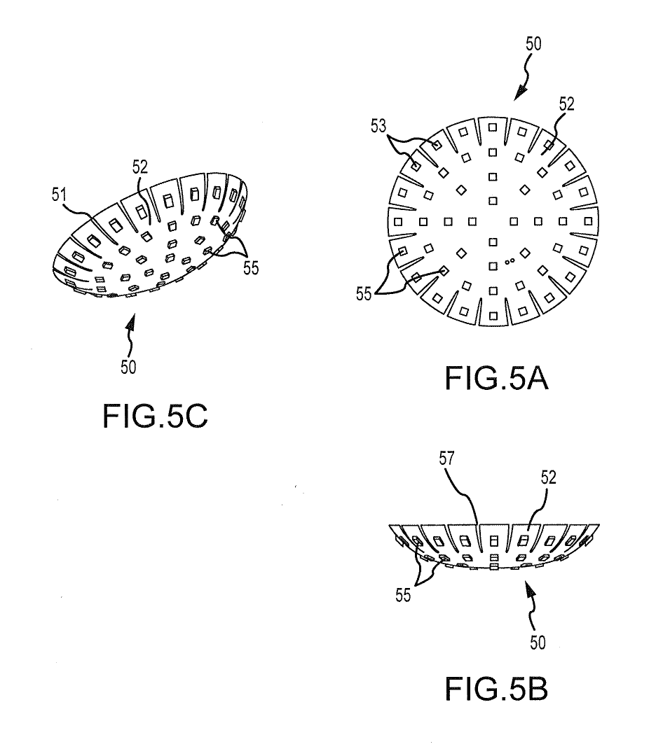

FIGS. 5A-5C illustrate a top view, a side view, and an isometric view of a curved PCB 50 according to an embodiment of the invention. More generally, a PCB according to embodiments of the invention includes at least a curved portion. For example, a PCB may be curved into a spherical or a dome shape. Alternatively, a PCB may be curved only along a single axis, forming a semi-cylindrical shape (not shown in figure). PCBs according to embodiments of the invention include a multitude of shapes having at least a curved portion. Such curved shaped PCBs may be used for other lighting fixtures such as wall fixtures, lanterns, or sconces, as examples.

The PCB 50 includes a PCB substrate 52. The PCB substrate 52 may be a metal based PCB, preferably aluminum or copper based. For example, the PCB substrate 52 may have an aluminum base layer, and a copper circuit layer, separated by a dielectric layer. As would be apparent to one of ordinary skill, other PCB configurations may be used. The PCB substrate 52 includes electrical connections (not shown) which provide electrical connection to light sources 55, which may be attached to the PCB 50. Although the light sources 55 are not attached when the PCB 50 is formed, the light sources 55 are shown in FIGS. 5A-5C to illustrate positioning of the light sources 55 on the PCB 50 in some embodiments of the invention. The PCB 50 includes cuts 51. The cuts 51 are made in the PCB substrate 52 to facilitate the forming of a curved portion of the PCB 50, as will be described in more detail below.

The curved PCB 50 may be used to orient light sources 55 in a manner that may improve dispersion of light emitted from the light sources 55. For example, as previously discussed, LED light sources are generally directional light sources, emitting light in the direction of orientation. By attaching LED light sources to a curved surface of the PCB 50, each of the light sources 55 will emit light in a direction perpendicular to the curve at the attachment location. As a result, the light emitted by all of the LED light sources may be more dispersed in comparison to LED light sources attached to a flat mounting surface.

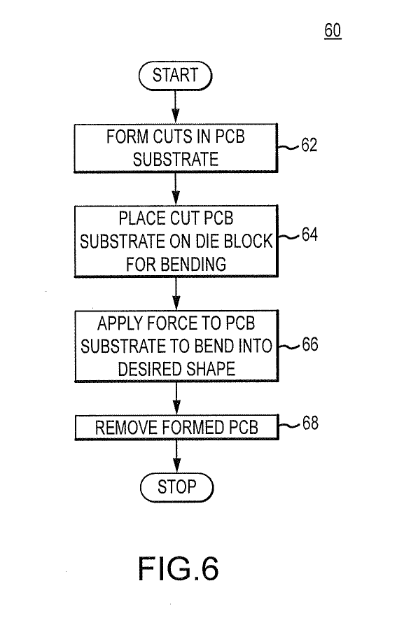

FIG. 6 illustrates a method 60 according to an embodiment of the invention for curving a PCB and creating a PCB having a three-dimensional configuration. The method 60 begins at step 62 with forming cuts (e.g., cuts 51 of PCB 50) in a PCB substrate that is substantially flat. The PCB substrate may be shaped accordingly to provide the desired curved shape. For example, a flat circular PCB substrate may be used for providing a round bowl shaped PCB. The cuts may be configured to facilitate the formation of the curvature on the PCB substrate in the following steps. For example, the cuts may be shaped and dimensioned in a manner that allows the flat PCB substrate to be shaped without cracking or breaking the electrical connections of the PCB substrate. The cuts, for example, may be generally triangular and radially oriented on a circular shaped PCB substrate.

An appropriate combination of cuts, notches or slits may be used to accommodate the desired three-dimensional shape of the PCB. Although cuts 51 are depicted along the perimeter of the curved PCB 50, cuts of varying shapes or sizes may be placed anywhere on the PCB as required to obtain the desired shape. For some embodiments, material may be removed so that overlap of material is prevented in the final curved PCB. In some cases it may be desirable to remove material 22 to further facilitate forming the PCB. In other embodiments, the curved PCB may appear to have no cuts or slits once formed in its desired three-dimensional shape. The number of cuts, as well as the cuts' length, thickness, or shape may be varied to obtain an appropriate pattern to accommodate forming the PCB into the desired shape. Cuts according to this pattern are made on the flat PCB substrate, and the cut PCB substrate may then be used to form the curved PCB. The cuts may be made using conventional cutting techniques, for example, punching, cutting pressing, and other cutting techniques.

At step 64 the cut PCB substrate is placed on a die block, or any other suitable forming die. Controlled force is applied at step 66 to the cut PCB substrate to slowly bend the flat PCB substrate into the desired shape. A press with the die block and punch may be used to provide a work surface and the force for bending the PCB substrate. At step 68 the curved PCB is removed from the die block and may now be used for attaching light sources.

As would be apparent to one of ordinary skill, the size, number, location, and other dimensions of the PCB substrate and the cuts will help determine the finished shape of the curved PCB. As such, various sizes of domes can be obtained, as well as other shapes of the curved PCBs can be achieved. As would be appreciated by those skilled in the art, cuts can be made on the PCB before or after printing of the electrical connections. In some embodiments, the PCB is cold formed to the desired shape. It would be apparent to one of ordinary skill, however, that heat may be applied during the forming process to facilitate shaping the surface without affecting the quality of the printed circuitry.

When using the curved PCB in a light module according to embodiments disclosed herein, one or more light sources 55 can be attached to the PCB at attachment locations 53. The attachment locations 53 are configured to provide locations at which the light sources 55 may be electrically coupled to the electrical connections of the curved PCB. In some embodiments, the attachment locations 53 expose a portion of the electrical connections and a light source 55 may be electrically connected, for example, soldered, to the exposed portion. In an example embodiment of the invention, the curved PCB includes a plurality of regularly patterned attachment locations. However, as would be apparent to one of ordinary skill, any number of attachment locations, in any regular or irregular pattern, can be manufactured on the PCB to achieve the desired light dispersion and distribution.

In some embodiments of a light module, the light module is built with an aluminum-based copper clad PCB. The curved PCB may have a thickness of approximately 2 mm or less. The light modules include a plurality of surface mounted LED light sources (SMT LEDs) connected to an LED driver. The LED driver is mounted in the interior of the module and may be connected to the SMT LEDs through the electrical connections of the curved PCB. Sufficient heat transfer from the plurality of LEDs may be provided with a curved PCB having a thickness of about 0.5 mm. The curved PCB connects to an aluminum inner heat sink, and the curved PCB snaps into place inside a second aluminum heat sink. A metallic ring may be used to maintain the curved PCB in contact with the aluminum heat sink. The curved PCB may be formed with various diameters without departing from the scope of the present invention. As previously described, light modules may be formed in have various sizes, for example, to be used with different sized conventional light fixtures. The curved PCB used in such various sized light modules may be suitable sized for the various applications and be formed and have various configurations according to embodiments of the invention.

From the foregoing it will be appreciated that, although specific embodiments of the invention have been described herein for purposes of illustration, various modifications may be made without deviating from the spirit and scope of the invention. Accordingly, the invention is not limited except as by the appended claims.

What is claimed is:

1. A light module, comprising:
a curved printed circuit board having electrical connections;
a plurality of light sources attached to the curved printed circuit board and electrically coupled to the electrical connections; and
a power supply electrically coupled to the plurality of light sources through the electrical connections of the curved printed circuit board, the power supply configured to provide power to the plurality of light sources.

2. The module of claim 1 wherein the plurality of light sources comprises a plurality of light emitting diode light sources.

3. The module of claim 1 wherein the plurality of light sources comprises a plurality of light sources configured to emit light directionally.

4. The module of claim 1, further comprising a covering.

5. The module of claim 1, further comprising a base plate to which the power supply is attached.

6. The module of claim 1 wherein the curved printed circuit board has a bowl shape.

7. The module of claim 1 wherein the curved printed circuit board includes radial cuts.

8. The module of claim 1, further comprising a heat sink thermally coupled to the curved printed circuit board.

9. The module of claim 1, further comprising pins electrically coupled to the power supply, the pins configured to engage a light fixture.

10. A printed circuit board, comprising:
a metallic substrate;
a layer of electrical connections;
a curved surface; and
an attachment location disposed on the curved surface and configured for the attachment of a light source and to provide electrical coupling of the light source to the layer of electric connections.

11. The printed circuit board of claim 10 wherein the attachment location is configured for the attachment of a light emitting diode light source.

12. The printed circuit board of claim 10 wherein the layer of electrical connections are formed in the printed circuit board.

13. The printed circuit board of claim 10 wherein the metallic substrate is circular.

14. The printed circuit board of claim 10, further comprising a plurality of cuts in the metallic substrate.

15. The printed circuit board of claim 14 wherein the plurality of cuts comprises at least one cut having a triangular shape and is radially oriented.

16. The printed circuit board of claim 10 wherein the metallic substrate comprises an aluminum substrate.

17. The printed circuit board of claim 10 wherein the attachment location comprises a region on the curved surface exposing a portion of the layer of electric connections.

18. The printed circuit board of claim 10 wherein the curved surface comprises a bowl-shaped surface.

19. A method for curving a printed circuit board, comprising:
forming a plurality of cuts on a substantially flat printed circuit board substrate; and
bending the printed circuit board substrate to form a curved printed circuit board.

20. The method of claim 19 wherein forming a plurality of cuts comprises forming a plurality of cuts having a triangular shape that are oriented radially on a circular printed circuit board substrate.

21. The method of claim 19 wherein bending the printed circuit board substrate comprises:
positioning the printed circuit board substrate on a die block; and
applying a force to the printed circuit board substrate to bend the printed circuit board substrate.

22. The method of claim 21 wherein forming the plurality of cuts comprises forming a plurality of cuts configured to prevent overlap of the printed circuit board substrate when bending the printed circuit board substrate to form the curved printed circuit board.

23. The method of claim 22 wherein the cuts are configured to provide an appearance of having no cuts in the curved printed circuit board.

24. The method of claim 22 wherein the cuts are configured to provide an appearance of having cuts in the curved printed circuit board.

25. The method of claim 19 wherein bending the printed circuit board substrate comprises bending the printed circuit board substrate to form a bowl-shaped printed circuit board.
